(19) United States
(12) Patent Application Publication
(10) Pub. No.: US 2021/0034200 A1
(43) Pub. Date: Feb. 4, 2021

(54) FOLDABLE DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Weiguo YOU, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/475,133

(22) PCT Filed: Apr. 16, 2019
(86) PCT No.: PCT/CN2019/082916

§ 371 Date: Jul. 1, 2019

(30) Foreign Application Priority Data
Feb. 28, 2019 (CN) 201910152273.0

(51) Int. Cl. G06F 3/044; H05K 5/00; H05K 5/02; G01D 5/241

(52) U.S. Cl. CPC G06F 3/0446; H05K 5/0017; G06F 2203/04102; G01D 5/2417; H05K 5/0226

(57) ABSTRACT

Provided is a foldable display device, including a display screen body and a rotating shaft; wherein the rotating shaft divides the display screen body into a first screen body and a second screen body; wherein the display screen body is used to be folded along the rotating shaft, and the display screen body is provided with capacitance detecting electrodes for detecting a folded state of the display screen body, and the capacitance detecting electrodes include a first electrode disposed on the first screen body and a second electrode disposed on the second screen body corresponding to the first electrode.

### FIELD OF THE INVENTION

The present invention relates to a display technology field, and more particularly to a foldable display device.

### BACKGROUND OF THE INVENTION

With the advancement of science and technology, people's pursuit of portable consumer electronic products is also becoming thinner and foldable. Nowadays, OLED display panels have been adopted by more and more electronic products, and flexible and foldable display panels have attracted much attention due to the foldability thereof.

In use of the existing foldable display device, when the display device is rotated to the state of FIG. 1, the screen display is turned off, and when it is rotated to the state of FIG. 2, the screen display is turned on. In order to detect the folded state of the screen, it is generally required to add a detecting structure to the foldable display device for detection. However, the existing detecting structure generally increases the thickness or weight of the screen, which is disadvantageous for the slimming of the foldable display device.

The existing detecting structure for detecting the folded state of the display device generally increases the thickness or weight of the screen, which is disadvantageous for the slimming of the display device.

### SUMMARY OF THE INVENTION

A foldable display device, including:

a display screen body;

a rotating shaft, dividing the display screen body into a first screen body and a second screen body;

wherein the display screen body is used to be folded along the rotating shaft, and the display screen body is provided with capacitance detecting electrodes for detecting a folded state of the display screen body, and the capacitance detecting electrodes include a first electrode disposed on the first screen body and a second electrode disposed on the second screen body corresponding to the first electrode; the first electrode and the second electrode are symmetrically distributed about the rotating shaft; The display screen body is provided with a display area and a non-display area, and the first electrode and the second electrode are both disposed in the non-display area.

Furthermore, the first electrode and the second electrode are both disposed adjacent to the rotating shaft.

Furthermore, the first electrode and the second electrode each include at least two detecting sub-electrodes that are parallel and independent of each other.

Furthermore, the display screen body is further provided with a control chip electrically connected to the first electrode and the second electrode.

Furthermore, the display screen body is provided with touch electrodes, and the touch electrodes are electrically connected to the control chip to form the capacitance detecting electrodes for detecting the folded state of the display screen body.

Furthermore, the touch electrodes include a horizontal touch electrode parallel to the rotating shaft and a vertical touch electrode perpendicular to the horizontal touch electrode; the horizontal touch electrode includes a plurality of rows of touch sub-electrodes which are mutually independent, and the touch sub-electrodes are electrically connected to the control chip to form the first electrode and the second electrode.

Furthermore, at least two rows of the touch sub-electrodes are electrically connected to the control chip to form the first electrode, and at least two rows of the touch sub-electrodes are electrically connected to the control chip to form the second electrode.

Furthermore, the capacitance detecting electrodes are self-capacitance detecting electrodes or mutual capacitance detecting electrodes.

A foldable display device, including:

a display screen body;

a rotating shaft, dividing the display screen body into a first screen body and a second screen body;

wherein the display screen body is used to be folded along the rotating shaft, and the display screen body is provided with capacitance detecting electrodes for detecting a folded state of the display screen body, and the capacitance detecting electrodes include a first electrode disposed on the first screen body and a second electrode disposed on the second screen body corresponding to the first electrode.

Furthermore, the first electrode and the second electrode are symmetrically distributed about the rotating shaft.

Furthermore, the first electrode and the second electrode are both disposed adjacent to the rotating shaft.

Furthermore, the first electrode and the second electrode each include at least two detecting sub-electrodes that are parallel and independent of each other.

Furthermore, the display screen body is provided with a display area and a non-display area, and the first electrode and the second electrode are both disposed in the non-display area.

Furthermore, the display screen body is further provided with a control chip electrically connected to the first electrode and the second electrode.

Furthermore, the display screen body is provided with touch electrodes, and the touch electrodes are electrically connected to the control chip to form the capacitance detecting electrodes for detecting the folded state of the display screen body.

Furthermore, the touch electrodes include a horizontal touch electrode parallel to the rotating shaft and a vertical touch electrode perpendicular to the horizontal touch electrode; the horizontal touch electrode includes a plurality of rows of touch sub-electrodes which are mutually independent, and the touch sub-electrodes are electrically connected to the control chip to form the first electrode and the second electrode.

Furthermore, at least two rows of the touch sub-electrodes are electrically connected to the control chip to form the first electrode, and at least two rows of the touch sub-electrodes are electrically connected to the control chip to form the second electrode.

Furthermore, the capacitance detecting electrodes are self-capacitance detecting electrodes or mutual capacitance detecting electrodes.

The folded degree of the display screen body can be determined by detecting the capacitance value of the capacitance formed by the first electrode and the second electrode. It is convenient and accurate, and compared to the mechanical detecting structure, the first electrode and the second electrode are small in size, and can be thinner and lighter, and can also be disposed inside the display screen body, which is advantageous for the slimming of the display device.

### BRIEF DESCRIPTION OF THE DRAWINGS

In order to more clearly illustrate the embodiments of the present invention and the prior art, the following figures will be described in the embodiments and the prior art are briefly introduced. It is obvious that the drawings are only some embodiments of the present invention, those of ordinary skill in this field can obtain other figures according to these figures without paying the premise.

FIG. 1 is a diagram of a foldable display device as being completely closed in the prior art of the present invention;

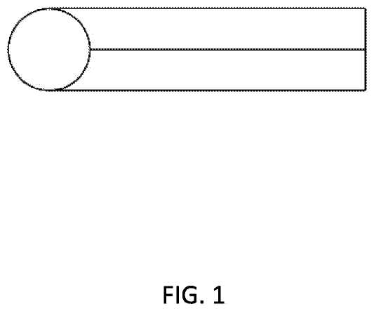

FIG. 2 is a diagram of a foldable display device as being completely opened in the prior art of the present invention;

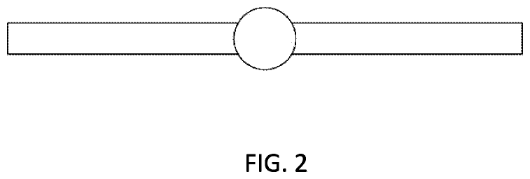

FIG. 3 is a structural diagram of a foldable display device according to embodiment one of the present invention;

FIG. 4 is a diagram as an angle is formed between a first screen body and a second screen body according to embodiment one of the present invention;

FIG. 5 is a diagram as a first electrode and a second electrode are obliquely disposed in embodiment one of the present invention;

FIG. 6 is a diagram as a first electrode and a second electrode are disposed perpendicular to a rotating shaft in embodiment one of the present invention;

FIG. 7 is a distribution diagram of a first electrode and a second electrode in embodiment two of the present invention;

FIG. 8 is a structural diagram of a foldable display device according to embodiment three of the present invention;

FIG. 9 is a structural diagram of a foldable display device according to embodiment four of the present invention.

### REFERENCE NUMERALS

11 first screen body; 12 second screen body; 13 display area; 14 non-display area; 20 rotating shaft; 31 first electrode; 32 second electrode; 33 control chip; 34 trace; 35 detecting sub-electrode; 41 touch sub-electrode; 42 vertical touch electrode

### DETAILED DESCRIPTION OF PREFERRED EMBODIMENTS

The following descriptions for the respective embodiments are specific embodiments capable of being implemented for illustrations of the present invention with referring to appended figures. The terms of up, down, front, rear, left, right, interior, exterior, side, etcetera are merely directions of referring to appended figures. Thus, the used directional terms are used to describe and understand the present invention, but the present invention is not limited thereto. In the figure, units with similar structures are denoted by the same reference numerals.

As regarding the foldable display device of the prior art, the present invention aims to the technical problem that the existing detecting structure for detecting the folded state of the display device generally increases the thickness or weight of the screen, which is disadvantageous for the slimming of the display device. The present invention can solve the aforesaid problems.

### Embodiment One

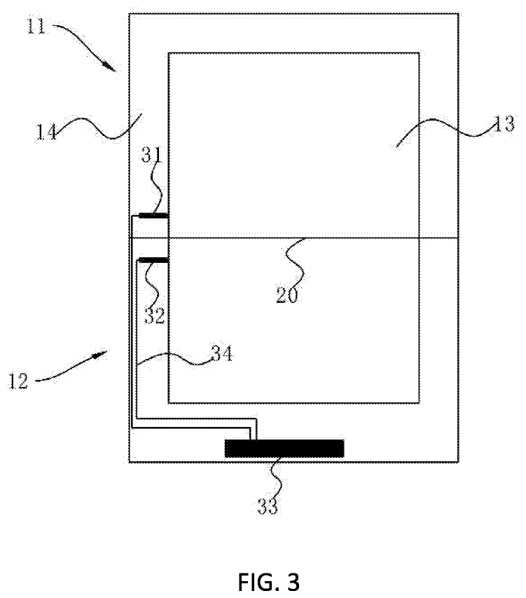

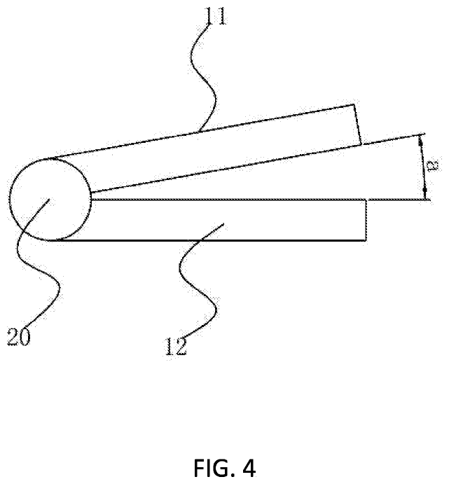

A foldable display device is shown in FIG. 3 and FIG. 4. The foldable display device includes a display screen body and a rotating shaft 20; the display screen body can be folded along the rotating shaft 20, and the rotating shaft 20 divides the display screen body into a first screen body 11 and a second screen body 12.

Specifically, the first screen body 11 and the second screen body 12 are rotatably connected to the rotating shaft 20 about the rotating shaft 20, and the first screen body 11 and the second screen body 12 are both rotatable about the rotating shaft 20.

When the display screen body needs to be opened or closed, by taking the first screen body 11 as an illustration, the first screen body 11 is rotated about the rotating shaft 20 in a direction away from the second screen body 12 to be parallel with the second screen body 12, and the display screen body is fully opened; the first screen body 11 is rotated about the rotating shaft 20 in a direction close to the second screen body 12 to be parallel with the second screen body 12, and the display screen body is fully closed.

The display screen body is provided with capacitance detecting electrodes for detecting a folded state of the display screen body; the capacitance detecting electrodes include a first electrode 31 disposed on the first screen body 11 and a second electrode 32 disposed on the second screen body 12 corresponding to the first electrode 31.

Specifically, an angle between the first screen body 11 and the second screen body 12 is a. It can be known to those skilled in the art that the capacitance value b of the capacitance formed by the first electrode 31 and the second electrode 32 is inversely proportional to a. Namely, as a is getting larger, a distance between the first electrode 31 and the second electrode 32 becomes larger, and b is getting smaller. The folded degree of the display screen body can be determined by monitoring the capacitance value b. It is convenient and accurate, and compared to the mechanical detecting structure, the first electrode 31 and the second electrode 32 are small in size, and can be thinner and lighter, and can also be disposed inside the display screen body, which is advantageous for the slimming of the display device.

Specifically, the display screen body is further provided with a control chip 33 electrically connected to the first electrode 31 and the second electrode 32. The control chip 33 provides a detection signal for the capacitance detecting electrodes. The capacitance detecting electrodes are self-capacitance detecting electrodes or mutual capacitance detecting electrodes.

When the capacitance detecting electrodes are self-capacitance detecting electrodes, the control chip 33 transmits the detection signal to the first electrode 31, and after the first electrode 31 receives the detection signal, the detection signal is transmitted to the control chip 33 via the trace 34; or the control chip 33 transmits the detection signal to the second electrode 32, and after the second electrode 32 receives the detection signal, the detection signal is transmitted to the control chip 33 via the trace 34, thereby determining the folded degree of the display screen body.

When the capacitance detecting electrodes are mutual capacitance detecting electrodes, the control chip 33 transmits the detection signal to the first electrode 31, and after the second electrode 32 receives the detection signal, the detection signal is transmitted to the control chip 33 via the trace 34; or the control chip 33 transmits the detection signal to the second electrode 32, and after the first electrode 31 receives the detection signal, the detection signal is transmitted to the control chip 33 via the trace 34, thereby determining the folded degree of the display screen body.

Specifically, the first electrode 31 and the second electrode 32 are symmetrically distributed about the rotating shaft 20.

It will be understood by those skilled in the art that a portion of the first electrode 31 corresponding to the second electrode 32 is larger, and then the capacitance value of the capacitance formed by the first electrode 31 and the second electrode 32 is larger. When the display screen body is folded, the change in the folded degree possesses a greater influence on the capacitance value of the capacitance formed by the first electrode 31 and the second electrode 32, so that the detected result of the folded degree of the display screen body is more accurate.

Furthermore, the first electrode 31 and the second electrode 32 are both disposed adjacent to the rotating shaft 20.

It will be understood by those skilled in the art that as the distance between the first electrode 31 and the second electrode 32 is smaller, the capacitance value of the capacitance formed by the first electrode 31 and the second electrode 32 is larger, so that the detected result of the folded degree of the display screen body is more accurate.

Furthermore, the display screen body is provided with a display area 13 and a non-display area 14, and the first electrode 31 and the second electrode 32 are both disposed in the non-display area 14 to prevent the first electrode and the second electrode from occupying the display area, thereby causing a reduction in the screen ratio of the display screen body.

Specifically, regarding the shapes of the first electrode 31 and the second electrode 32, only the case that the first electrode 31 and the second electrode 32 are both rectangular is illustrated in FIG. 3. In the specific implementations, the first electrode 31 and the second electrode 32 may also have other shapes, such as a wave shape or an arc shape, which are not illustrated here. The first electrode 31 and the second electrode 32 are disposed in the non-display area 14. The first electrode 31 and the second electrode 32 are arranged in a wave shape or an arc shape without increasing the width of the non-display area 14, and the area of the first electrode 31 and the second electrode 32 can be increased. Thereby, the capacitance value of the capacitance formed by the first electrode 31 and the second electrode 32 is increased, so that the detected result of the folded degree of the display screen body is more accurate.

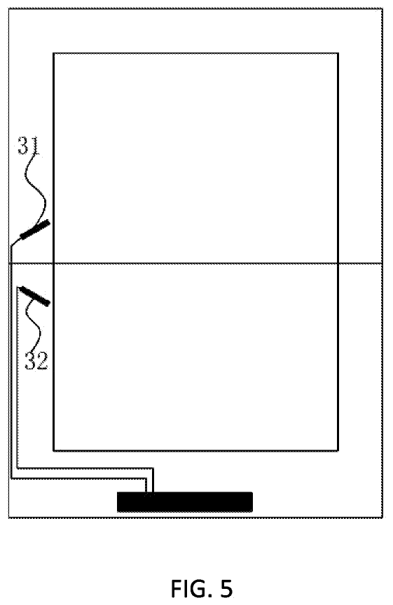

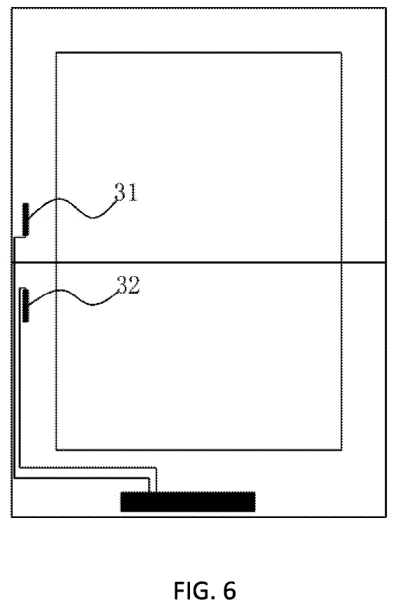

Specifically, regarding to the positional arrangement of the first electrode 31 and the second electrode 32, only the case that the first electrode 31 and the second electrode 32 are parallel to the rotating shaft 20 is illustrated in FIG. 3. In the specific implementations, as shown in FIG. 5 and FIG. 6, the first electrode 31 and the second electrode 32 may also be disposed obliquely or perpendicular to the rotating shaft 20.

### Embodiment Two

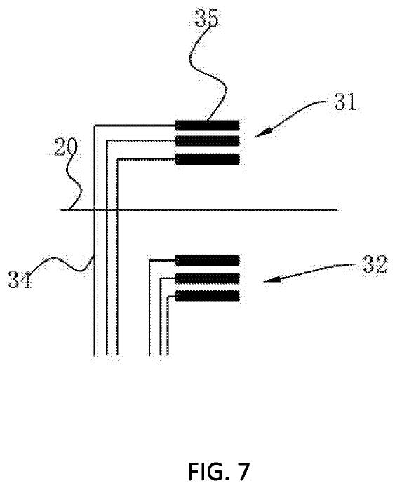

A foldable display device is shown in FIG. 7. This embodiment differs from the first embodiment only in that the first electrode 31 and the second electrode 32 each include at least two detecting sub-electrodes 35 that are parallel and independent of each other. The detecting sub-electrodes 35 are all electrically connected to the control chip 33 through the traces 34.

A capacitance is formed between the detecting sub-electrodes 35 corresponding to each other, and the detection sensitivity is improved by a plurality of capacitances, thereby accurately detecting the folded state of the display screen body.

Specifically, in FIG. 7, only the case that the first electrode 31 includes three detecting sub-electrodes 35 is illustrated. In the specific implementations, the first electrode 31 may further include two or more detecting sub-electrodes 35.

### Embodiment Three

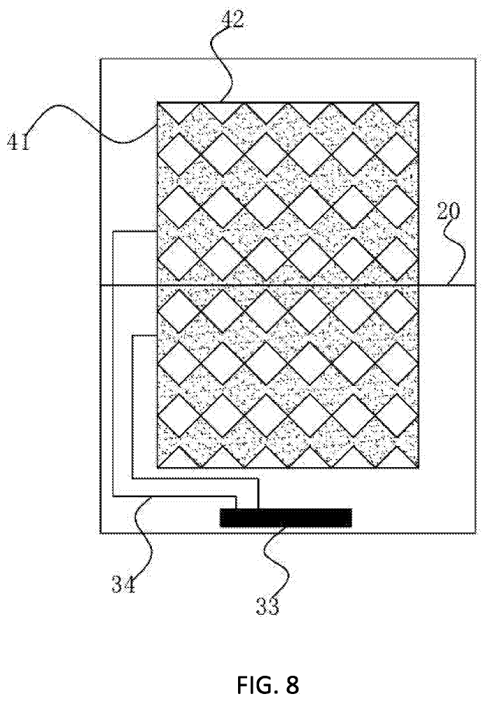

A foldable display device is shown in FIG. 8. This embodiment differs from the first embodiment only in that the formation of the capacitance detecting electrodes is different.

Furthermore, the display screen body is provided with touch electrodes, and the touch electrodes are electrically connected to the control chip 33 to form the capacitance detecting electrodes for detecting the folded state of the display screen body.

The touch electrodes include a horizontal touch electrode parallel to the rotating shaft 20 and a vertical touch electrode 42 perpendicular to the horizontal touch electrode; the horizontal touch electrode includes a plurality of rows of touch sub-electrodes 41 which are mutually independent, and the vertical touch electrode 42 includes a plurality of columns of touch sub-electrodes which are mutually independent, i.e. all rows of the touch sub-electrodes 41 are insulated from each other; the touch sub-electrodes 41 are electrically connected to the control chip 33 to form the first electrode 31 and the second electrode 32.

By using the touch electrodes provided by the display device as the capacitance detecting electrode, it is not necessary to additionally provide a capacitance detecting electrode, thereby reducing the production cost.

### Embodiment Four

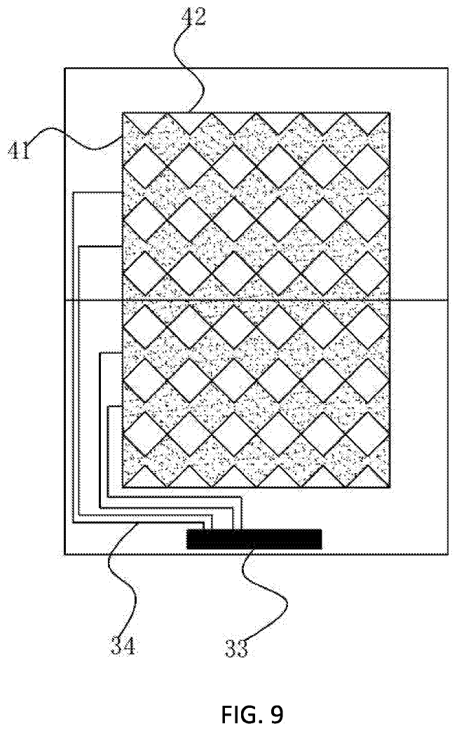

A foldable display device is shown in FIG. 9. This embodiment differs from the first embodiment only in that the first electrode 31 and the second electrode 32 each include a plurality of rows of touch sub-electrodes 41.

Specifically, at least two rows of touch sub-electrodes 41 are electrically connected to the control chip 33 to form the first electrode 31. At least two rows of touch sub-electrodes 41 are electrically connected to the control chip 33 to form the second electrode 32.

Specifically, in FIG. 9, only the case that the first electrode 31 includes three touch sub-electrodes 41 is illustrated. In the specific implementations, the first electrode 31 may further include two or more touch sub-electrodes 41.

The benefits of the present invention are: the folded degree of the display screen body can be determined by detecting the capacitance value of the capacitance formed by the first electrode 31 and the second electrode 32. It is convenient and accurate, and compared to the mechanical detecting structure, the first electrode 31 and the second electrode 32 are small in size, and can be thinner and lighter, and can also be disposed inside the display screen body, which is advantageous for the slimming of the display device.

In summary, although the above preferred embodiments of the present invention are disclosed, the foregoing preferred embodiments are not intended to limit the invention, those skilled in the art can make various kinds of alterations and modifications without departing from the spirit and scope of the present invention. Thus, the scope of protection of the present invention is defined by the scope of the claims.

What is claimed is:

1. A foldable display device, including:
a display screen body;
a rotating shaft, dividing the display screen body into a first screen body and a second screen body;
wherein the display screen body is used to be folded along the rotating shaft, and the display screen body is provided with capacitance detecting electrodes for detecting a folded state of the display screen body, and the capacitance detecting electrodes include a first electrode disposed on the first screen body and a second electrode disposed on the second screen body corresponding to the first electrode;
the first electrode and the second electrode are symmetrically distributed about the rotating shaft; The display screen body is provided with a display area and a non-display area, and the first electrode and the second electrode are both disposed in the non-display area.

2. The foldable display device according to claim 1, wherein the first electrode and the second electrode are both disposed adjacent to the rotating shaft.

3. The foldable display device according to claim 1, wherein the first electrode and the second electrode each include at least two detecting sub-electrodes that are parallel and independent of each other.

4. The foldable display device according to claim 1, wherein the display screen body is further provided with a control chip electrically connected to the first electrode and the second electrode.

5. The foldable display device according to claim 4, wherein the display screen body is provided with touch electrodes, and the touch electrodes are electrically connected to the control chip to form the capacitance detecting electrodes for detecting the folded state of the display screen body.

6. The foldable display device according to claim 5, wherein the touch electrodes include a horizontal touch electrode parallel to the rotating shaft and a vertical touch electrode perpendicular to the horizontal touch electrode; the horizontal touch electrode includes a plurality of rows of touch sub-electrodes which are mutually independent, and the touch sub-electrodes are electrically connected to the control chip to form the first electrode and the second electrode.

7. The foldable display device according to claim 6, wherein at least two rows of the touch sub-electrodes are electrically connected to the control chip to form the first electrode, and at least two rows of the touch sub-electrodes are electrically connected to the control chip to form the second electrode.

8. The foldable display device according to claim 1, wherein the capacitance detecting electrodes are self-capacitance detecting electrodes or mutual capacitance detecting electrodes.

9. A foldable display device, including:
a display screen body;
a rotating shaft, dividing the display screen body into a first screen body and a second screen body;
wherein the display screen body is used to be folded along the rotating shaft, and the display screen body is provided with capacitance detecting electrodes for detecting a folded state of the display screen body, and the capacitance detecting electrodes include a first electrode disposed on the first screen body and a second electrode disposed on the second screen body corresponding to the first electrode.

10. The foldable display device according to claim 9, wherein the first electrode and the second electrode are symmetrically distributed about the rotating shaft.

11. The foldable display device according to claim 10, wherein the first electrode and the second electrode are both disposed adjacent to the rotating shaft.

12. The foldable display device according to claim 10, wherein the first electrode and the second electrode each include at least two detecting sub-electrodes that are parallel and independent of each other.

13. The foldable display device according to claim 9, wherein the display screen body is provided with a display area and a non-display area, and the first electrode and the second electrode are both disposed in the non-display area.

14. The foldable display device according to claim 10, wherein the display screen body is further provided with a control chip electrically connected to the first electrode and the second electrode.

15. The foldable display device according to claim 14, wherein the display screen body is provided with touch electrodes, and the touch electrodes are electrically connected to the control chip to form the capacitance detecting electrodes for detecting the folded state of the display screen body.

16. The foldable display device according to claim 15, wherein the touch electrodes include a horizontal touch electrode parallel to the rotating shaft and a vertical touch electrode perpendicular to the horizontal touch electrode; the horizontal touch electrode includes a plurality of rows of touch sub-electrodes which are mutually independent, and the touch sub-electrodes are electrically connected to the control chip to form the first electrode and the second electrode.

17. The foldable display device according to claim 16, wherein at least two rows of the touch sub-electrodes are electrically connected to the control chip to form the first electrode, and at least two rows of the touch sub-electrodes are electrically connected to the control chip to form the second electrode.

18. The foldable display device according to claim 9, wherein the capacitance detecting electrodes are self-capacitance detecting electrodes or mutual capacitance detecting electrodes.
